(19) United States
(12) Patent Application Publication
(10) Pub. No.: US 2009/0121288 A1
(43) Pub. Date: May 14, 2009

(54) MULTIPLE GATE FIELD EFFECT TRANSISTOR STRUCTURE AND METHOD FOR FABRICATING SAME

(76) Inventor: Paul PATRUNO, Austin, TX (US)

Correspondence Address: WINSTON & STRAWN LLP;PATENT DEPARTMENT, 1700 K STREET, N.W., WASHINGTON, DC, 20006, US

(21) Appl. No.: 12/200,400

(22) Filed: Aug. 28, 2008

(30) Foreign Application Priority Data
Sep. 11, 2007 (EP) EP 07291089.6

(51) Int. Cl. H01L 29/00; H01L 21/20

(52) U.S. Cl. 257/347; 438/479; 257/E29.001; 257/E21.09

(57) ABSTRACT

The present invention relates to a Multiple Gate Field Effect Transistor structure and a method for fabricating same. The Multiple Gate Field Effect Transistor structure includes a fin structure made from at least one active semiconductor layer of a silicon on insulator (SOI) structure on a buried insulator of the structure. The Multiple Gate Field Effect Transistor structure also includes an insulator of at least one high-k layer of a material having a dielectric constant that is higher than silicon oxide. This has the advantage that the high-k layer acts as a better etch stop than silicon oxide during formation and cleaning of the fin resulting in a lower recess and undercut effect on the socket of the fin. This leads to a higher stability of the formed fin and enables a smooth finishing of the fin by etching and cleaning steps.

### BACKGROUND

The present invention relates to a Multiple Gate Field Effect Transistor structure having a fin-like structure for forming therein a transistor channel of the multiple gate field effect transistor structure. The fin-like structure is formed from at least one active semiconductor layer of a Silicon On Insulator (SOI) structure on a buried insulator of the SOI structure. The present invention also relates to a method for fabricating such structures. This method comprises providing a SOI substrate comprising at least one active semiconductor layer, a buried insulator and a carrier substrate, and forming from the semiconductor layer a fin structure on the insulator, wherein the fin structure forms a region for a transistor channel of the Multiple Gate Field Effect Transistor structure.

Scaling of device dimensions is a primary factor driving improvements in integrated circuits manufacturing. Due to limitations in scaling gate oxide thickness and source/drain junction depth, the scaling of a conventional planar MOSFET device beyond the 32 nm process will be difficult if not impossible. Therefore, new device structures like Multiple Gate or Multigate Field Effect Transistors (MuGFETs) have been developed to overcome the technological challenges of the MOSFET devices. The Multigate Field Effect Transistor is a MOSFET which incorporates more than one gate into a single device. That means, the channel is surrounded by several gates on multiple surfaces, allowing more suppression of “off’-state leakage current. Multiple gates also enable an enhanced drive current in an “on” state. This leads to lower power consumption and enhanced device performance.

The so-called double-gate MOSFET uses two gates to control the channel what results to the effect that short-channel effects can be greatly suppressed. A specific variant of a non-planar double-gate MOSFET is a FinFET consisting of a channel formed in a vertical Si fin controlled by a double-gate formed on both longitudinal sides of the fin. The fin is made thin enough when viewed from above such that the two gates control the entire fully-depleted channel film. Thus, the dimensions of the fin determine the effective channel length of the transistor device. The FinFET is, as a non-planar device, more compact in comparison to conventional planar MOS transistors, enabling higher transistor density and smaller overall microelectronics. In a further implementation consistent with the principles of the invention, a triple-gate MOSFET is provided as well.

### SUMMARY OF THE INVENTION

The present invention therefore provides a Multiple Gate Field Effect Transistor structure and a method for fabricating same, wherein the Multiple Gate Field Effect Transistor structure can be near ideally prepared to overcome several related issues.

The Multiple Gate Field Effect Transistor structure includes an insulator comprising at least one high-k layer of a material having a dielectric constant that is higher than silicon oxide. This has the advantage that the high-k layer underlying the semiconductor layer of the SOI type substrate acts as a better etch stop than silicon oxide during formation and cleaning of the fin resulting in a lower recess and undercut effect on the socket of the fin. This leads to a higher stability of the formed fin and enables a smooth finishing of the fin by etching and cleaning steps. High-k materials are clearly defined in relation to the dielectric constant of silicon dioxide.

In a preferred embodiment of the invention, the insulator comprises at least one silicon nitride layer. Silicon nitride has a higher dielectric constant than silicon dioxide and is therefore especially well suited to act as an etch stop during etch and cleaning of the semiconductor fin. A silicon nitride layer directly under the semiconductor layer from which the fin is formed, results in a minimum vertical recess and fin undercut. However, if silicon nitride is used as insulator material directly under the semiconductor layer of the SOI type substrate, the bottom corner profile of the fin is not rounded but rather tapered, which might lead to undesirable effects for the resulting Field Effect Transistor (FET) structure.

It is therefore particular advantageous if the insulator comprises a thin silicon oxide layer between the high-k layer and the semiconductor layer of the SOI type substrate. Using this variant of the invention, the silicon oxide layer being above the high-k layer may be etched and trimmed during the formation and cleaning of the fin, wherein the underlying high-k layer functions as an etch stop so that a further undercut of the fin can be prevented. This way, the advantage of rounded corners at the bottom of the fin can be conserved wherein a recess and undercut of the fin during the fabrication process can be minimized. Thus, the combination of the upper oxide and the high-k layer enables an optimized undercut to be obtained automatically underneath the FET during etching.

According to another preferred example of the present invention, the insulator comprises a silicon oxide layer between the high-k layer and the carrier substrate of the SOI type substrate. The lower silicon oxide under the high-k layer allows for a good bonding between the high-k layer and the carrier substrate of the SOI type substrate which is, in particular, necessary if the SOI type structure is manufactured by a SMART-CUT® process using bonding, implantation and cleaving steps to form the SOI type substrate.

It is especially beneficial if the insulator comprises a layer stack consisting of a lower silicon oxide layer, a silicon nitride layer and an upper silicon oxide layer. This idea includes a replacement of the conventionally used buried oxide (BOx) of a SOI structure by a composite oxide-nitride-oxide (ONO) stack as the insulator of the SOI type substrate. This improves not only the definition of the size and the profile of the fin but also enhances the stability of the structure due to a good bonding strength between the lower oxide and the carrier substrate of the SOI type substrate. In particular, by the upper oxide, rounded corners at the bottom of the fin can be realized and, by the use of the underlying silicon nitride layer as a hard etch stop layer, the fin vertical recess can be perfectly controlled when the upper oxide layer, used as a buffer, will be totally removed around the fin, thereby adjusting the upper oxide layer thickness as proposed is the best way to provide optimization for both the profile under the fin and the electrical characteristics of the MuGFET device.

In a favorable configuration of the present invention, the silicon nitride layer is formed with a thickness of 10 to 200 nm. Using such a thickness, the vertical recess at the bottom of the fin can be reduced to about 2 to 4 nm and the horizontal recess can be totally cancelled.

It has been shown as advantageous if the upper silicon oxide layer is formed with a thickness of 2 to 20 nm, preferably with a thickness of 5 to 15 nm, and more preferably with a thickness of 3 to 12 nm. Because the total height of the fin is given by the sum of the thickness of the semiconductor layer used to make the fin plus the thickness of the silicon oxide layer undercut below the fin, the smaller the upper oxide layer the lower is the total fin height variation. On the other hand, a certain thickness of the upper oxide layer is necessary to allow a formation of rounded corners at the bottom of the fin during etching and cleaning steps of the fin fabrication process. The above thickness values of 2 to 20 nm are a compromise between the above mentioned requirements, wherein with the thickness values of 5 to 15 nm a low undercut can be combined with a good roundness of the corners, and thickness values of 3 to 12 nm reduce the undercut optimally wherein the corners are essentially round to provide good FET characteristics.

In a particular example of the invention, the lower silicon oxide layer is formed with a thickness of about 10 to 100 nm. Although not critical for the purpose of the present invention, this thickness range helps to improve the mechanical stability of the resulting MuGFET structure since it assures a good bonding strength between the carrier substrate and the upper part of the MuGFET structure.

According to a beneficial variant of the method of the present invention, the forming of the fin-like structure comprises an over-etch of the insulator. A controlled over-etch can lead to an improved FET structure because it results in an increased undercut below the fin, wherein a larger horizontal recess will help to improve the propagation of the gate electric field under the FET device for a better back-gate effect.

### BRIEF DESCRIPTION OF THE DRAWINGS

In the following, features and benefits of advantageous embodiments of the present invention are explained exemplarily with reference to the accompanying figures, in which:

FIG. 1 shows schematically and in principle main parts of a MuGFET structure using a FinFET structure as an example;

FIGS. 2a to 2b show schematically an example of a sequence of process steps of the method of the present invention;

FIG. 3 shows schematically a fin geometry according to a first embodiment of the present invention;

FIG. 4 shows schematically a fin geometry according to a second embodiment of the present invention;

FIG. 5 shows schematically a fin geometry according to a third embodiment of the present invention; and

FIG. 6 shows schematically the fin geometry according to the third embodiment of the present invention shown in FIG. 5, whereas the impact of adjusting the thickness of the layer of the upper oxide is shown.

### DETAILED DESCRIPTION OF THE PREFERRED EMBODIMENTS

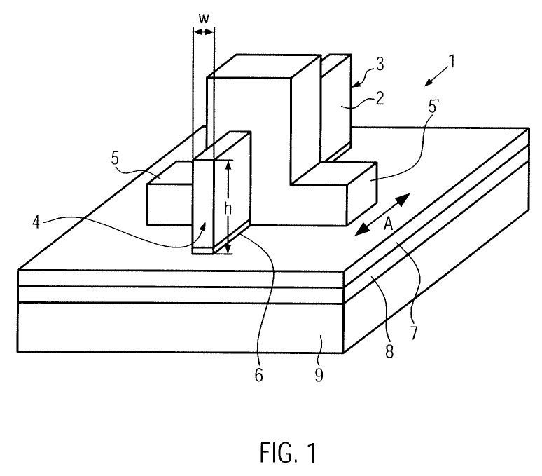

FIG. 1 shows schematically and in principle main parts of a MuGFET structure using a FinFET structure 1 as an example. The FinFET 1 comprises a fin-like structure 2 being formed from an active semiconductor top layer of a SOI type substrate. In the example shown, the semiconductor top layer and, therefore, the fin 2 consists of silicon, wherein the fin 2 can consist in other not shown embodiments of the invention of other semiconductor materials like strained silicon, SiGe, SiC, Ge and/or a Group III-V or A(III)-B(V) compound.

As an improvement, strained silicon can be used to replace the top silicon layer of the SOI type substrate. The use of a strained silicon layer greatly improves electron mobility with (100) orientation of the silicon, thereby providing higher transistor current.

In FIG. 1, the height h of the fin 2 is about 50 nm, but can be in other not shown embodiments of the invention between 30 to 100 nm. The width w of the fin 2 is in the example shown about 20 nm and can be in other examples of the invention typically between 10 and 25 nm. The fin 2 is that region of the FinFET in which a conducting channel is formed when the FinFET 1 is in operation. Thus, the dimensions of the fin 2 determine the effective channel length of the FinFET 1.

The ends of the fin 2 in its longitudinal direction A are connected with a source 3 and a drain 4 of the FinFET 1.

On both longitudinal sidewalls of the fin 2, gates 5, 5′ are provided. In the example shown in FIG. 1, the gates 5, 5′ are wrapped around the fin 2.

The present invention can also be applied to produce MuGFET's with multiple drains and multiple sources, such as Tri-Gate FET's, or Gate-All-Around FET's having a similar concept to FinFET's except that the gate material surrounds the channel region on all sides, wherein a Gate-All-Around FET has, depending on design, two or four effective gates. It is also applied to any types of MuGFET's when the gates made are independent-gates and each gate can be electrically activated independently of the others.

The substrate on which the fin 2 of FIG. 1 is formed has on top an insulator with a high-k layer having a higher dielectric constant that silicon oxide such as a silicon nitride layer 7. The high-k layer 7 is formed on a lower silicon oxide layer 8, which is on a carrier substrate 9. In the example shown, the carrier substrate 9 is of bulk silicon, but can be in other not shown embodiments of the invention of another material.

As an improvement, the carrier substrate 9 can be a high-resistivity substrate. This way, the resulting MuGFET structures will be able to address Millimeter Wave (MMW) applications and higher frequencies applications up to G band (140 to 220 GHz) for low cost and low power CMOS digital and RF applications.

Between the bottom of the silicon fin 2 and the silicon nitride layer 7, there is a residual part of a former upper silicon layer 6. The upper silicon oxide 6 has in FIG. 1 a thickness of about 10 nm, but can have according to other embodiments of the invention a thickness of about 2 to 20 nm, preferably about 5 to 15 nm, and more preferably about 3 to 12 nm.

The silicon nitride layer 7 of FIG. 1 has a thickness of 20 nm, which is in other examples of the invention about 10 to 200 nm. The thickness of the lower silicon oxide layer 8 is for example about 10 to 100 nm, preferably about 70 to 80 nm. This way, there is layer stack under the fin 2 in FIG. 1 consisting of an ONO (oxide/nitride/oxide) structure.

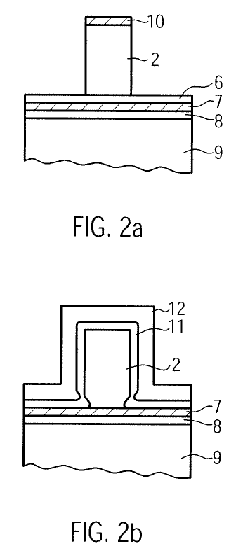

FIGS. 2a to 2b show schematically a sequence of process steps of the method of the present invention. With reference to FIG. 2a, the method starts with a step of providing a SOI type substrate formed in the example shown by a SMART-CUT® process and consisting in the example of a the carrier silicon bulk substrate 9, a lower silicon oxide layer 8, a silicon nitride layer 7, an upper silicon oxide layer 6 and an upper silicon layer for forming the fin 2. The silicon layer is covered with a SbN4 and Si02 stack layer 10 and then patterned by electron beam lithography and etch to result in the fin 2.

During etching of the fin 2, the underlying silicon oxide layer 6 as well a part of the silicon nitride layer 7 is removed around the fin 2. Due to the etch of the silicon oxide layer 6, the fin 2 is partly underetched. During the formation of the fin 2, the silicon nitride layer 7 acts as an etch stop and shows only negotiable underetch effects under the fin 2, that means, the horizontal recess of the silicon nitride layer 7 is negligible. The result of the etching of the fin is exemplarily shown in FIG. 4 explained below.

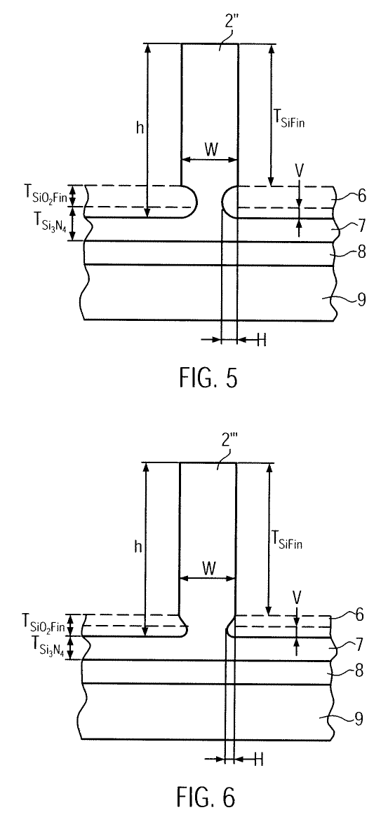

The fin 2 is finished with the trimming and subsequent cleaning of the fin 2 resulting in a larger underetch effect of the silicon oxide layer 6, as shown in FIG. 5 described below.

In a next step demonstrated in FIG. 2b, an insulating layer 11 is deposited to serve as the future gate oxide. Thereafter, agate electrode layer 12 of any conductive material is deposited around the insulator layer 11.

The following steps to manufacture a MuGFET device are to be done according the current practice with subsequent steps like completion of the gate stack deposition and gate patterning followed by spacer formation and source/drain formation. The contacts to the transistor regions and other devices are later realized as well as the appropriate number of metal and insulator layers are laid on the wafers and are inter-connected through vias holes together to assemble an integrated circuit.

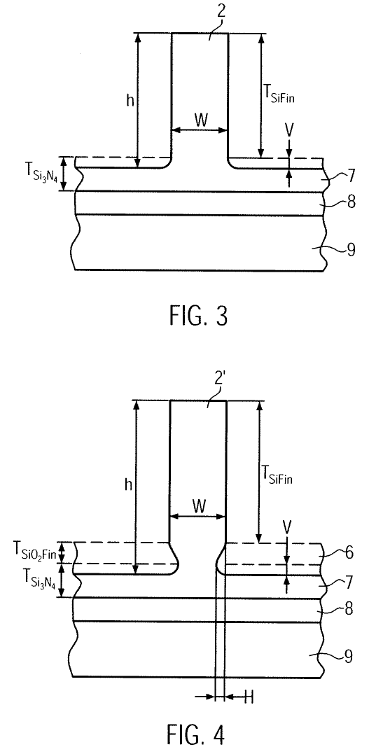

FIG. 3 shows schematically a geometry of a fin 2 according to a first embodiment of the present invention. The fin 2 is formed on the surface of a silicon nitride layer 7 with a thickness of 10 to 30 nm, the silicon nitride layer 7 being formed on top of an oxide layer 8 with a thickness of 70 to 80 nm.

During the formation of the fin 2, the underlying silicon nitride layer 7 acts as an etch stop and reduces, therefore, greatly the vertical recess V and the lateral recess and undercut of the fin 2. According to a particular example, it has been shown that the vertical recess V went to a 2 nm to 4 nm range from about 15 nm and that the horizontal recess was completely reversed. As a consequence of reversing of the profile of the lateral recess or undercut of the fin 2, the bottom corner profile of the fin 2 changes from rounded to tapered which might not be a desirable effect.

FIG. 4 shows schematically a geometry of a fin 2′ according to a second embodiment of the present invention. The fin 2′ is formed on a layer stack consisting of a lower silicon oxide layer 8, a silicon nitride layer 7 and an upper silicon oxide layer 6 formed on top of the layer stack directly under the fin 2′. That means, in comparison to the example shown in FIG. 3, the top nitride layer 7 is replaced by the 10 nm to 15 nm range top oxide layer 6. By means of the upper silicon oxide layer 6, the advantage of rounded corners when etching and subsequently cleaning the fin 2′ during the fabrication process can be conserved. As shown in FIG. 4, there is not only a vertical recess V but also a horizontal recess H in the region under the fin 2′, leading to rounded corner formation at the bottom of the fin 2′. Moreover, the used layer structure keeps the benefit of perfectly controlling the fin 2′ vertical recess V by using the silicon nitride layer 7 as a hard etch stop when the silicon oxide layer 6, used as a buffer, will be totally removed around the fin 2′.

FIG. 5 shows schematically a geometry of a fin 2″ according to a third embodiment of the present invention. The fin 2″ is an improved variant of the fin 2′ of FIG. 4. The fin 2″ was well controlled over-etched in order to increase the undercut below the fin 2″. The larger horizontal recess H helps to round the bottom corners of the fins, which helps to improve the propagation of the gate electric field of the resulting FinFET 1 for a better back-gate effect.

FIG. 6 shows the same geometry of the fin 2″ according to the third embodiment of the present invention shown in FIG. 5, whereas the thickness of the upper silicon oxide layer 6 is reduced by half. This reduces by about the same value the horizontal recess H and helps to achieve a better compromise between recess profile and bottom corner rounding of the resulting fin 2′″.

H˜½T_{Si02Fin}

The total height h variation of the fin 2′, 2″, 2′″ including the vertical recess V on each side of the fin 2′, 2″, 2′″ is given by the sum of the thickness T_{SiFin} of the silicon layer used to make the fin 2′, 2″, 2′″ plus the thickness TSi02Fin of the silicon oxide layer 6 undercut below the fin 2′, 2″, 2′″ plus the vertical recess V in the silicon nitride layer 7.

h=T_{SiFin}+T_{Si02Fin}+V

The variation of the fin height h, knowing that the vertical recess V is very small and varies only within a few tens of nanometer, is therefore predominantly dependent on the control by the manufacturing process of the thickness T_{SiFin} of the silicon layer used to make the fin 2′, 2″, 2′″ and of the thickness T_{Si02Fin} of the silicon oxide layer 6 being the top layer of the insulator (AlterBOx) of the SOI type substrate used to fabricate the FinFET 1.

This makes the reverse AlterBox process suggested by the present invention far superior for lateral recess and undercut profile control maintaining rounded corners at the bottom of the fin 2′, 2″, 2′″, when compared with the approach shown in FIG. 3 where the top layer of the insulator (AlterBOx) of the SOI type substrate is the silicon nitride layer 7. The proposed process still provides a nitride etch-stop layer 7 for a successful control of the vertical total fin height variation.

Moreover, the replacement of the conventional buried oxide layer (BOx) by a composite oxide-nitride-oxide (ONO) as the insulator layer of the SOI type substrate used to fabricate the fin 2′, 2″, 2′″ improves a number of characteristics of the resulting MuGFET structures and may also add with a thin ONO stack the capability to control the substrate potential to adjust, for example, the threshold voltage of the produced transistors.

The MuGFET structures fabricated by the present invention show very good RDF (Random Dopant Fluctuation) due to the lightly doped body, an improved Short-Channel effect due to improved electrostatic behavior, near-ideal sS (subthreshold Siope) and good DIBL (Drain Induced Barrier Lowering) characteristics. Since it is possible to control by the present invention the fin dimensions and the fin profile, ail performance variations of the resulting MuGFET structures can be kept within a tight budget. This will ensure the MuGFET structures of the present invention to provide strong compelling advantages and a continued transistor scaling when compared with planar structures or MuGFET structures formed on conventional SOI substrates.

What is claimed is:

1. A method for fabricating a Multiple Gate Field Effect Transistor structure, which comprises:
providing a silicon on insulator (SOI) substrate comprising at least one active semiconductor layer, a buried insulator and a carrier substrate, and
forming from the semiconductor layer a fin structure on the insulator, with the fin structure forming a region for a transistor channel of the multiple gate field effect transistor structure,
wherein the insulator comprises at least one high-k layer of a material having a dielectric constant that is higher than silicon oxide.

2. The method of claim 1, wherein the semiconductor layer from which the fin structure is formed includes at least one layer of silicon, strained silicon, SiGe, SiC, Ge or a Group III-V compound.

3. The method of claim 1, wherein the insulator comprises at least one silicon nitride layer.

4. The method of claim 1, wherein the insulator comprises a silicon oxide layer that is positioned between the high-k layer and the semiconductor layer of the SOI substrate.

5. The method of claim 1, wherein the insulator comprises a silicon oxide layer positioned between the high-k layer and the carrier substrate of the SOI substrate.

6. The method of claim 1, wherein the insulator comprises a layer stack that includes a lower silicon oxide layer, a silicon nitride layer and an upper silicon oxide layer.

7. The method of claim 6, wherein the silicon nitride layer is formed with a thickness of 10 to 200 nm.

8. The method of claim 6, wherein the upper silicon oxide layer is formed with a thickness of 2 to 20 nm.

9. The method of claim 6, wherein the lower silicon oxide layer is formed with a thickness of about 10 to 100 nm.

10. The method of claim 1, wherein the forming of the fin structure comprises an over-etch of the insulator.

11. A Multiple Gate Field Effect Transistor (MuGFET) structure having a fin structure for forming therein a transistor channel, the fin structure comprised of at least one active semiconductor layer of a silicon on insulator (SOI) structure on a buried insulator of the structure, wherein the insulator comprises at least one high-k layer of a material having a dielectric constant that is higher than silicon oxide.

12. The MuGFET structure of claim 11, wherein the insulator comprises at least one silicon nitride layer.

13. The MuGFET structure of claim 11, wherein the insulator comprises silicon oxide and is positioned between the high-k layer and the part of the fin structure formed from the semiconductor layer of the SOI substrate.

14. The MuGFET structure of claim 11, wherein and the insulator comprises a silicon oxide layer that is positioned between the high-k layer and a carrier substrate of the SOI substrate.

15. The MuGFET structure of claim 11, wherein the insulator comprises a stack that includes a lower silicon oxide layer, a silicon nitride layer and an upper silicon oxide layer.

16. The MuGFET structure of claim 15, wherein the silicon nitride layer has a thickness of 10 to 200 nm.

17. The MuGFET structure of claim 15, wherein the upper silicon oxide layer has a thickness of 3 to 20 nm.

18. The MuGFET structure of claim 15, wherein the lower silicon oxide layer has a thickness of about 10 to 100 nm.
